(19) United States
(12) Patent Application Publication
(10) Pub. No.: US 2008/0124874 A1
(43) Pub. Date: May 29, 2008

(54) Methods of Forming Field Effect Transistors Having Silicon-Germanium Source and Drain Regions

(75) Inventors: Sang Jean Park, Fishkill, NY (US); Jong Ho Yang, Fishkill, NY (US)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/556,394

(22) Filed: Nov. 3, 2006

(51) Int. Cl. H01L 21/336

(52) U.S. Cl. 438/285; 257/E21.403

(57) ABSTRACT

Methods of forming field effect transistors include forming an insulated gate electrode on a non-SiGe semiconductor substrate and then selectively etching the semiconductor substrate to define source and drain region trenches on opposite sides of the insulated gate electrode. A step is performed to remove native oxide layers from sidewalls of the source and drain region trenches. The removal of the native oxide is followed by recessing the sidewalls of the source and drain region trenches by selectively wet etching the sidewalls of the source and drain region trenches. This step of wet etching the sidewalls of the source and drain region trenches may include exposing the sidewalls to a cleaning solution including ammonium hydroxide (NH₄OH). A step is then performed to epitaxially grow SiGe source and drain regions in the source and drain region trenches. This step of epitaxially growing SiGe source and drain regions may include epitaxially growing in-situ doped SiGe source and drain regions of first conductivity type in the source and drain region trenches.

### FIELD OF THE INVENTION

The present invention relates to integrated circuit fabrication methods and, more particularly, to methods of fabricating field effect transistors in integrated circuit substrates.

### BACKGROUND OF THE INVENTION

The electrical properties of field effect transistors may be improved by increasing the mobility of charge carriers in the channel regions of the field effect transistors. One technique to increase the mobility of charge carriers in a channel region includes adding lattice strain to the channel region. Lattice strain may be added to the channel region by generating a lattice mismatch between the channel region and source/drain regions of the field effect transistor. In some cases, a lattice mismatch may be generated by forming a heterojunction between the channel region and the source/drain regions. One technique to form a heterojunction includes forming the channel region as a silicon region and the source/drain regions as SiGe source/drain regions, which have a different lattice constant relative to the silicon channel region.

A SiGe source/drain region may be formed by etching a source/drain region trench in a silicon substrate and then epitaxially growing a SiGe source/drain region in the trench, using a sidewall and/or bottom of the trench as a “seed” during epitaxial growth. Techniques to form source/drain region trenches may include isotropic etching techniques and anisotropic etching techniques. Isotropic etching techniques can be advantageous because they typically yield relatively high levels of strain by virtue of the fact that the trench sidewalls may have close proximity to the channel region. Unfortunately, isotropic etching techniques may suffer from unstable process control and poor repeatability. In contrast, anisotropic etching techniques typically provide excellent process control, but frequently do not yield the high levels of strain that can be achieved with isotropic etching techniques.

### SUMMARY OF THE INVENTION

Embodiments of the present invention include methods of forming field effect transistors having SiGe source and drain regions and a non-SiGe semiconductor channel region (e.g., silicon channel region), which is strained by a lattice mismatch between the SiGe source and drain regions and the channel region. According to these methods, a field effect transistor may be formed by forming an insulated gate electrode on a non-SiGe semiconductor substrate and then selectively etching the semiconductor substrate to define source and drain region trenches on opposite sides of the insulated gate electrode. A step is then performed to remove native oxide layers from sidewalls of the source and drain region trenches. The removal of the native oxide is followed by recessing the sidewalls of the source and drain region trenches by selectively wet etching the sidewalls of the source and drain region trenches. This step of wet etching the sidewalls of the source and drain region trenches may include exposing the sidewalls to a cleaning solution including ammonium hydroxide (NH₄OH). A step is then performed to epitaxially grow SiGe source and drain regions in the source and drain region trenches. This step of epitaxially growing SiGe source and drain regions may include epitaxially growing in-situ doped SiGe source and drain regions of first conductivity type in the source and drain region trenches.

According to further aspects of these embodiments, the step of selectively etching the semiconductor substrate to define source and drain regions trenches includes etching the semiconductor substrate using a anisotropic etching step, such as reactive ion etching (RIE). In addition, the step of removing the native oxide from sidewalls of the source and drain region trenches may include exposing the sidewalls of the source and drain region trenches to a first cleaning solution, which may include an oxide etchant such as hydrofluoric acid (HF).

Additional embodiments of the present invention include methods of forming a field effect transistor by forming a gate electrode on a non-SiGe semiconductor substrate and then forming source and drain regions (e.g., lightly doped source and drain regions) in the substrate by selectively implanting source and drain region dopants of first conductivity type into the substrate, using the gate electrode as a first implant mask. Sidewall spacers are then formed on sidewalls of the gate electrode. The formation of the spacers is followed by a step of implanting additional source and drain region dopants into the substrate, using the gate electrode and sidewall spacers as an implant mask. The semiconductor substrate is then selectively etched to define source and drain region trenches on opposite sides of the insulated gate electrode. A native oxide material and contaminants are then removed from sidewalls of the source and drain region trenches by exposing the sidewalls of the trenches to a diluted hydrofluoric acid (HF) cleaning solution. These sidewalls are then recessed by exposing the cleaned sidewalls to another cleaning solution containing ammonium hydroxide. An epitaxial growth step is then performed to grow SiGe source and drain regions from the sidewalls of the source and drain region trenches. This epitaxial growth step may be an in-situ doped epitaxial growth step.

### BRIEF DESCRIPTION OF THE DRAWINGS

FIGS. 1A-1E illustrate methods of forming field effect transistors according to embodiments of the present invention.

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. Like numbers refer to like elements throughout.

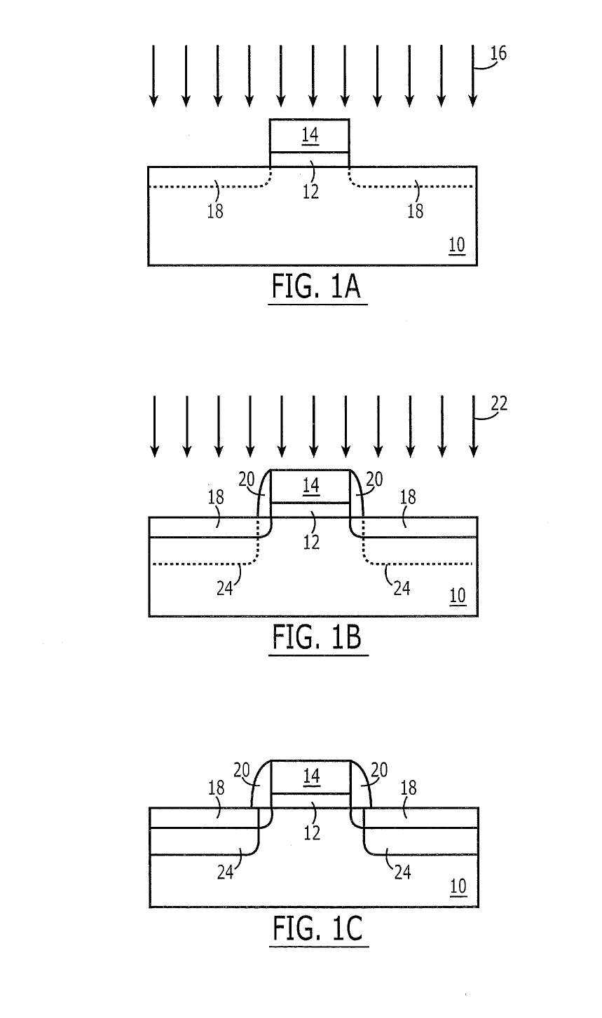

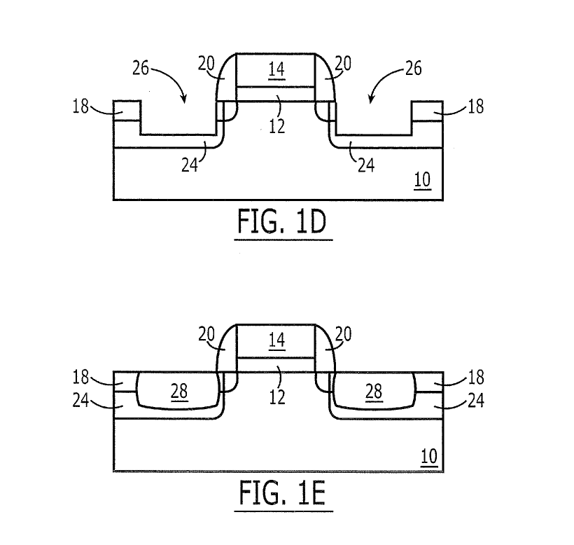

Methods of forming field effect transistors according to some embodiments of the present invention include forming trench-based SiGe source and drain regions using a combination of anisotropic and isotropic etching techniques and cleaning steps to form source and drain region trenches, which are then filled with SiGe using an epitaxial growth step. As illustrated by FIGS. 1A-1E, these methods include forming an insulated gate electrode on a semiconductor substrate 10. This insulated gate electrode is illustrated as including a gate insulating layer 12 and a gate electrode 14 on the gate insulating layer 12, as illustrated by FIG. 1A. The gate insulating layer 12 and the gate electrode 14 may be formed by depositing an electrically insulating layer on the semiconductor substrate 10 and depositing an electrically conductive gate electrode layer on the electrically insulating layer. These two layers are then selectively patterned to define an insulated gate electrode. Source and drain region dopants 16 are then implanted into the semiconductor substrate 10 at a first dose level and a first energy level. During this implanting step, the insulated gate electrode is used as an implant mask. The first dose level and the first energy level may be selected so that the implanted dopants result in the formation of relatively shallow and lightly doped source/drain regions 18 (e.g., LDD regions) on opposite sides of the insulated gate electrode.

Referring now to FIG. 1B, sidewall insulating spacers 20 are formed on sidewalls of the insulated gate electrode. These spacers 20 may be formed by conformally depositing an electrically insulating layer and then etching back the deposited layer to define the spacers 20. Thereafter, additional source and drain region dopants 22 may be implanted into the substrate 10, using the insulated gate electrode and sidewall spacers 20 as an implant mask. This implant of the source and drain region dopants 22 may be performed at a second dose level and second energy level, which are greater than the first dose level and first energy level, respectively. As illustrated by FIG. 1C, the substrate 10 may be annealed to drive-in the implanted dopants and thereby define relatively highly doped source and drain regions 24.

Referring now to FIG. 1D, an anisotropic etching step is then performed to define source and drain region trenches 26 that extend into the substrate 10, on opposite sides of the insulated gate electrode. This anisotropic etching step may be performed using a reactive ion etching (RIE) technique, for example. A cleaning step is then performed to remove native oxide material, etching residues and contaminants/impurities from the sidewalls and bottoms of the source and drain region trenches 26. This cleaning step may be performed by exposing the source and drain region trenches 26 to a first cleaning solution comprising hydrofluoric acid (HF). This cleaning step may be performed for a sufficient duration to reduce a concentration of carbon impurities at the sidewalls of the trenches 26 to a level less than about 1×10¹³/cm⁻².

As illustrated by FIG. 1E, a relatively short duration isotropic etching step is then performed to recess the sidewalls and bottoms of the source and drain region trenches 26. This etching step may be performed by exposing the trenches 26 to a second cleaning/etching solution comprising ammonium hydroxide (NH₄OH). Thereafter, the trenches 26 are filled by epitaxially growing SiGe source and drain regions 28 in the trenches 26, using the sidewalls and bottoms of the trenches 26 as epitaxial seed regions. These SiGe source and drain regions 28 may be in-situ doped during the epitaxial growth step, or may be doped after formation by selectively implanting dopants into the SiGe source and drain regions 28.

In the drawings and specification, there have been disclosed typical preferred embodiments of the invention and, although specific terms are employed, they are used in a generic and descriptive sense only and not for purposes of limitation, the scope of the invention being set forth in the following claims.

1. A method of forming a field effect transistor, comprising the steps of:
forming an insulated gate electrode on a semiconductor substrate;
selectively etching the semiconductor substrate to define source and drain region trenches on opposite sides of the insulated gate electrode;
removing native oxide material from sidewalls of the source and drain region trenches;
recessing the sidewalls of the source and drain region trenches by selectively etching the sidewalls of the source and drain region trenches; and
epitaxially growing SiGe source and drain regions in the source and drain region trenches.

2. The method of claim 1, wherein said epitaxially growing step comprises epitaxially growing in-situ doped SiGe source and drain regions of a first conductivity type in the source and drain region trenches.

3. The method of claim 1, wherein said selectively etching step comprises selectively etching the semiconductor substrate to define source and drain region trenches on opposite sides of the insulated gate electrode using a reactive ion etching process.

4. The method of claim 1, wherein said removing step comprises exposing the sidewalls of the source and drain region trenches to a cleaning solution comprising hydrofluoric acid.

5. The method of claim 4, wherein said recessing step comprises exposing the sidewalls of the source and drain region trenches to an etching solution comprising ammonium hydroxide.

6. A method of forming a field effect transistor, comprising the steps of:
forming a gate electrode on a semiconductor substrate;
forming first source and drain regions in the semiconductor substrate by selectively implanting source and drain region dopants of a first conductivity type into the semiconductor substrate, using the gate electrode as a first implant mask;
forming sidewall spacers on the gate electrode;
forming second source and drain regions in the semiconductor substrate by selectively implanting source and drain region dopants of a first conductivity type into the semiconductor substrate, using the gate electrode and the sidewall spacers as an implant mask;
selectively etching the semiconductor substrate to define source and drain region trenches on opposite sides of the insulated gate electrode;
recessing the sidewalls of the source and drain region trenches by exposing the sidewalls to a cleaning solution comprising ammonium hydroxide; and
epitaxially growing SiGe source and drain regions in the source and drain region trenches, respectively.

7. The method of claim 6, wherein said recessing step is preceded by a step of removing native oxide material from the sidewalls using a diluted HF cleaning solution.

8. The method of claim 6, wherein said epitaxially growing step comprises epitaxially growing in-situ doped SiGe source and drain regions in the source and drain region trenches, respectively.

9. The method of claim 6, wherein a concentration of carbon impurities at the sidewall of the source region trench is less than 1×10¹³/cm⁻².
